(19) United States
(12) Patent Application Publication
(10) Pub. No.: US 2007/0114889 A1
(43) Pub. Date: May 24, 2007

(54) Chip level packaging for wireless surface acoustic wave sensor

(75) Inventors: Cornel Cobianu, Bucharest (RO); Ion Georgescu, Bucharest (RO); Vlad Buiculescu, Bucharest (RO)

Correspondence Address: Attorney, Intellectual Property;Honeywell International Inc., 101 Columbia Rd., P.O. Box 2245, Morristown, NJ, 07962, US

(73) Assignee: Honeywell International

(21) Appl. No.: 11/286,064

(22) Filed: Nov. 21, 2005

(51) Int. Cl. H01L 41/00

(52) U.S. Cl. 310/338; 310/348

(57) ABSTRACT

A sensor packaging system and methodology includes a plastic substrate configured to include a gap for receiving and maintaining an acoustic wave sensor. An antenna can be printed directly on the plastic substrate and connected electrically to the acoustic wave sensor for the transmission and receipt of data from and to the acoustic wave sensor. The antenna can be flip chip mounted to the acoustic wave sensor, which can be implemented, for example, in the context of a Surface Acoustic Wave (SAW) sensor chip. Such a SAW sensor chip can includes a plurality of metal electrodes located on the same surface of the plastic substrate as the SAW sensor chip.

### TECHNICAL FIELD

Embodiments are generally related to sensing devices and methods thereof. Embodiments are also related to wireless sensors. Embodiments are additionally related to surface acoustic wave sensors utilized in pressure sensing applications.

### BACKGROUND OF THE INVENTION

Wireless sensors are utilized in a number of sensing applications, including, for example, pressure and temperature sensing in automobile tires. Wireless sensors are typically mounted in association with antenna and receiving units. In recent years, for example, like a mobile communication unit such as a cellular phone, or a wireless LAN (Local Area Network) based on the so-called IEEE (Institute of Electronic and Electronics Engineers) 802.11 standard, various wireless communication techniques have been remarkably developed, and in accordance with this, various techniques concerning an antenna element as an inevitably provided member to perform wireless communication have also been developed.

As an antenna element, for example, one in which a radiation electrode, a surface electrode or the like is formed on a cylindrical dielectric is known. This kind of antenna element is generally installed at the outside of an equipment body and is used. However, in the antenna element of such a type that it is disposed at the outside and is used, there are problems that miniaturization of the equipment is obstructed, high mechanical strength is required, and the number of parts is increased.

A problem with conventional wireless sensor technology is that it is difficult to integrate the antenna on the wireless sensor chip for operation frequencies lower than 2.4 GHz. A need exists for a robust technology for chip level packaging and antenna and impedance matching circuit fabrication on a flexible substrate. An example where a need for an improved wireless sensor packaging system and methodology exists is in the area of wireless tire pressure sensing. A system and methodology that meets this continuing need is disclosed in greater detail herein.

### BRIEF SUMMARY

The following summary is provided to facilitate an understanding of some of the innovative features unique to the embodiments disclosed and is not intended to be a full description. A full appreciation of the various aspects of the embodiments can be gained by taking the entire specification, claims, drawings, and abstract as a whole.

It is, therefore, one aspect of the present invention to provide for an improved wireless sensing device including two parts bonded one to the other and an associated antenna.

It is another aspect of the present invention to provide for an improved wireless acoustic wave sensor.

It is yet another aspect of the present invention to provide for a system for packaging a wireless acoustic wave sensor and an associated antenna. Such an acoustic wave sensor can be configured from two components bonded together by varying technologies, such as, for example glass frit, plastic, or direct bonding.

The aforementioned aspects and other objectives and advantages can now be achieved as described herein. A sensor packaging system and methodology are described herein, that generally includes a plastic substrate configured to include a gap for receiving and maintaining an acoustic wave sensor. An antenna can be printed directly on the plastic substrate and connected electrically to the acoustic wave sensor for the transmission and receipt of data from and to the acoustic wave sensor. The antenna can be “flip chip” mounted to the acoustic wave sensor, which can be implemented, for example, in the context of a Surface Acoustic Wave (SAW) sensor chip. Such a SAW sensor chip can includes a plurality of metal electrodes located on the surface of quartz wafer. In addition, such a SAW sensor can be configured with a quartz cover and the SAW quartz chip may be bonded one to the other utilizing, for example, glass frit technology, so that an all quartz packaging (AQP) configuration, also referred to as “zero level packaging” can be obtained. Such a glass frit technology can be applied to any type of quartz SAW sensor packaging, where a low stress robust packaging technology is desired. Depending on application requirements, any type of low stress quartz-to quartz bonding can be utilized, such as, for example, direct quartz-to-quartz bonding, plastic bonding, etc.

An insulating polyimide can be utilized to selectively encapsulate one or more surfaces of the SAW sensor chip. A sensing diaphragm is generally maintained by the SAW sensor chip. The sensing diaphragm can be configured to include a recessed area. A gel that functions as a pressure transmitting element can be located within the recessed area. The plastic substrate can be configured as a dielectric substrate, which is flexible. The acoustic wave sensor generally includes a quartz cover and the gap formed in the plastic substrate accommodates the quartz cover. The antenna is printed directly on the plastic substrate by maskless ink-jet deposition. Additionally, the acoustic wave sensor can be mounted on the antenna with a plurality of bonding pads associated with the acoustic wave sensor positioned on a plurality of corresponding bonding pads associated with the antenna.

The sensor packaging system disclosed herein thus includes a dielectric substrate and a wireless acoustic wave sensor comprising at least one quartz component. An antenna is generally attached to the wireless acoustic wave sensor on the dielectric substrate utilizing ink-jet maskless printing, thereby providing a sensor for the wireless transmission and receipt of sensor data. The antenna printed on the dielectric substrate preferably operates in a frequency range of approximately 100 KHz to 2.4 GHz. The dielectric substrate comprises a hole for maintaining the wireless acoustic wave sensor, wherein the hole is configured so that a quartz cover associated with the wireless acoustic wave sensor can be accommodated therein for a decreased total thickness of the acoustic wave sensor.

The system and methodology disclosed herein thus relates to a technology for the chip level packaging of the wireless SAW sensors. A direct writing technology for the antenna and impedance matching circuit fabrication on a plastic substrate can be combined with the flip chip technology for attaching the antenna chip to the wireless SAW quartz sensor chip. Metal layers for printed antenna and matching circuit, vias filling and final plastic housing of the packaged wireless sensor can be accomplished utilizing a maskless, ink-jet printing process. This technology can be adapted for use with any type of wireless sensor that includes an antenna external to the sensor chip.

### BRIEF DESCRIPTION OF THE DRAWINGS

The accompanying figures, in which like reference numerals refer to identical or functionally-similar elements throughout the separate views and which are incorporated in and form a part of the specification, further illustrate the embodiments and, together with the detailed description, serve to explain the embodiments disclosed herein.

FIG. 1 illustrates a side view of a glass fritted all quartz packaged surface acoustic wave sensor that can be implemented in accordance with a preferred embodiment;

FIG. 2 illustrates a side view of antenna printing on a plastic substrate configured with a gap therein, in accordance with a preferred embodiment;

FIG. 3 illustrates a side view of a wireless acoustic wave sensor system, which can be implemented in accordance with a preferred embodiment; and

FIG. 4 illustrates a perspective view of a maskless ink-jet deposition printing system, which can be adapted for use in accordance with a preferred embodiment.

### DETAILED DESCRIPTION

The particular values and configurations discussed in these non-limiting examples can be varied and are cited merely to illustrate at least one embodiment and are not intended to limit the scope thereof.

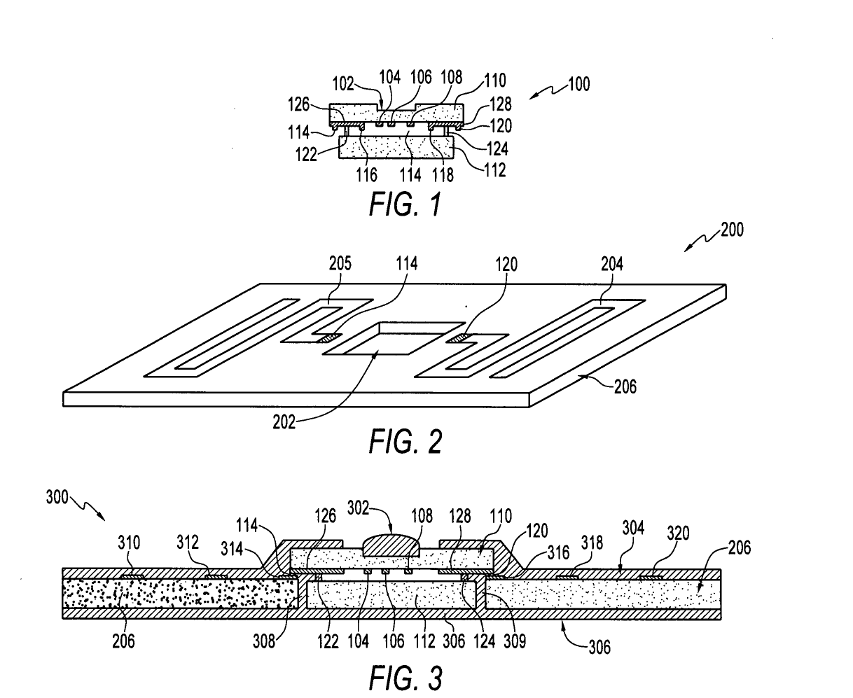

FIG. 1 illustrates a side view of a surface acoustic wave sensor 100 that can be implemented in accordance with a preferred embodiment. The surface acoustic wave sensor 100 depicted in FIG. 1 can be implemented as a quartz-based Surface Acoustic Wave (SAW) sensor chip and generally includes a one or more SAW sensors 104, 106, 108, which are connected to and maintained by a SAW quartz chip 110. The sensor 100 also includes a diaphragm 102 that is maintained by the SAW quartz chip 110. A reference chamber 114 can be located between the SAW quartz chip 110 and a quartz cover 112.

In accordance with a preferred embodiment, the hermetic sealing of the SAW quartz chip 110 and the quartz cover 112 can be accomplished utilizing glass frit technology, in which a glass wall closes the reference pressure chamber of the sensor. The glass frit spacers 122 and 124 depicted in FIG. 1 represent schematically the glass frit process, which allows the metal electrodes 126 and 128 to be located outside of the reference chamber 114 while still preserving the hermetic structure of the pressure chamber. Metal electrodes 126 and 128 are also supported by the SAW quartz chip 110 and are respectively separated from the quartz cover 112 by glass frit spacers 122 and 124. Metal-to-metal flip chip components 114, 116 and 118, 120 are respectively connected to the metal electrodes 126 and 128.

FIG. 2 illustrates a side view of an antenna 204, 205 printed on a plastic substrate 206 configured with a gap or hole 202 therein, in accordance with a preferred embodiment. Note that in FIGS. 1-4, identical or similar parts or elements are generally indicated by identical reference numerals. The hole 202 is formed in plastic substrate 206 in order to accommodate the quartz cover 112. Metal-to-metal surface mounting components 114 and 120, which are often referred to as so-called “bumps” by those skilled in the art are also depicted in FIG. 2. Existing flip chip technology can be applied for the realization of conductive bumps on a plastic substrate necessary for the connection of the sensor pad to the antenna. The bumps 114 and 120 may possess, for example, a diameter of approximately 100 micrometers, and can be configured from metal or conductive polymers. Antenna 204, 205 can be configured from metal, conductive plastic or a combination thereof, depending upon design considerations.

FIG. 3 illustrates a side view of a wireless acoustic wave sensor system 300, which can be implemented in accordance with a preferred embodiment. System 300 generally includes the plastic substrate 206 depicted in FIG. 3 and is surrounded by a polyimide layer 304 and a polyimide layer 306. One or more polyimide via fillings 308 and 309 are also provided between portions of the plastic substrate 206. Antenna components 310, 312 and 314 depicted in FIG. 3 form the antenna 205 depicted in FIG. 2, while antenna components 316, 318 and 320 forms the antenna 204 depicted in FIG. 2.

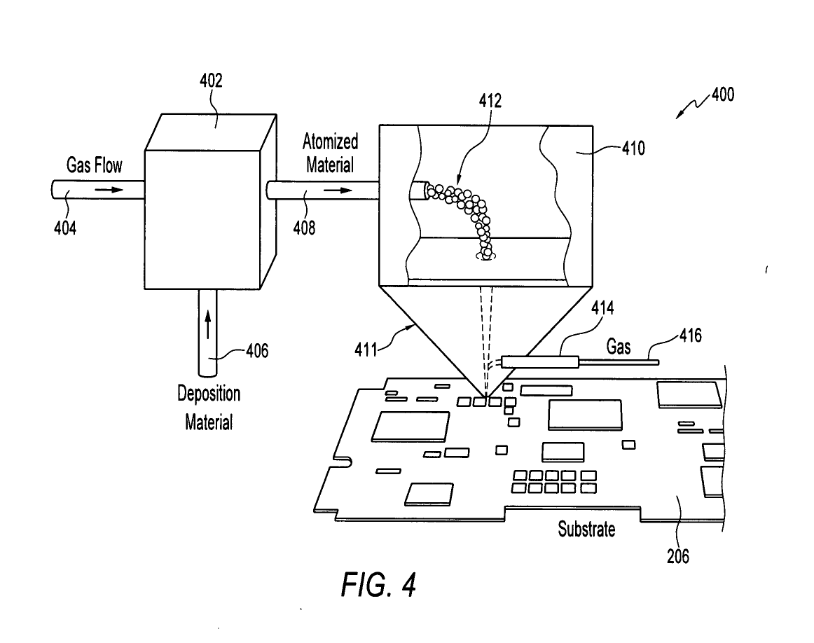

The resulting sensor or system 300 can be implemented in the context of any type of wireless sensor where an antenna such as antenna 204, 205 and associated antenna components 310, 312, 314 and 315, 318, 320 are attached to the output of sensor 300. The configuration depicted in FIG. 1, for example, demonstrates chip level packaging of the wireless SAW quartz sensor 100 for pressure measurement, where a region with thinned quartz is utilized to implement the pressure sensing diaphragm 102. The interrogation signal comes to the sensor antenna 204, 205 and the sensor response (echo) is transmitted back to the sensor antenna 204, 205, which can further send the electromagnetic signal to a sensor interrogator. The antenna 204, 205 can be fabricated by ink-jet technology (i.e., see FIG. 4) on the plastic substrate 206 followed by surface mounting of the antenna chip to the sensor chip by the flip chip technology and finishing with the final housing of the sensor 100 with a plastic layer.

The new aspect of the antenna fabrication for wireless sensors is the application of the technology for the metal deposition by ink-jet deposition of the metal layer as indicated in FIG. 2. Thus, the wire antenna with potential reliability problems can be eliminated. In addition, the circuit for impedance matching can be also performed by means of this ink-jet technology, where the passive circuit can be printed on the dielectric substrate. The layout of the sensor antenna 204, 205 can be obtained from electrical and magnetic simulations, where the operation frequency, gain and input impedance are generally responsible for the size of the antenna 204, 205.

The selective deposition of the metal layers for the formation of antenna 204, 205 can be accomplished utilizing a maskless, ink-jet process, as indicated in FIG. 4 where the shape of the antenna 204, 205, can be directly controlled by means of a computer during metal paste deposition. Any shape of the printed antenna 204, 205 can be obtained via this maskless ink-jet printing process. Without limiting the generality of the types of antennas, FIGS. 2-3 demonstrate an example of the layout of the meander-like antenna 204, 205, which is deposited on the plastic substrate 206. Note that antenna 204, 205 can be implemented as a folded dipole, patch, spiral or loop antenna, depending upon design considerations. Note that system 400 can be utilized in such a manner that an impedance matching circuit and its layout are ink-jetted on the antenna substrate 206.

The concepts illustrated in FIGS. 1-4 relate to the fabrication of an antenna plastic chip that can be provided with a hole or gap 202 formed in the region where the future cover 112 of the quartz sensor 100 will be accommodated. This allows for a good contact between the various sensor parts, which are placed in contact by flip chip technology and can thus reduce the height of the packaged device or system 300. This substrate 206 can be, for example, Kapton®, or any plastic material with a glass transition temperature higher than 170° C. degrees. Note that Kapton® is a polyimide film developed by the DuPont Corporation which can remain stable in a wide range of temperatures, from −269° C. to 400° C. Kapton® is used in, among other things, flexible printed circuits and spacesuits. As an alternative to ink-jet deposition of the metal paste for the fabrication of antenna 204, 205, the screen-printed technology can be used to obtain the desired layout of the antenna 204, 205.

FIG. 4 illustrates a perspective view of a maskless inkjet deposition printing system 400 that can be adapted for use in accordance with an embodiment. Note that system 400 depicted in FIG. 4, generally includes a unit 402 that is connected to tubes 404, 406 and 408. Gas flow into component 402 occurs via tube 404, while deposition material is provided through tube 406. Atomized material 412 exits unit 402 via tube 408 and then enters an ink-jet print head 410 having a nozzle 411. Gas 416 can be expelled from the nozzle 411 via a tube 414. Ink jet printing of the antenna 204, 205 occurs on substrate 206 as described earlier.

The novelty of the solution illustrated in FIGS. 1-4 lies in the fact that the limited height of the resulting packaged wireless sensor or system 300 can be obtained by fitting the quartz cover 112 within the hole 202 configured in the plastic substrate 206. The distance between the bond pads measured on the sensor chip being equal to the distance between the bond pads of antenna 204, 205 measured on the antenna chip will allow a good alignment and a reliable electrical connection of the sensor 100 and antenna 204, 205. This principle can be applied to any type of antenna printed on the plastic substrate 206. For the case of glass frit technology utilized to bond the two parts of the SAW sensor, the sum of thicknesses of the plastic substrate 206 and the height of the bumps 114 and 120 located on plastic substrate should be equal to the sum of the thickness of quartz cover 122 and the glass frit spacer height 122 and 128. Such a configuration can create a planar surface on the backside of the resulting package or system 300. The two bumps 114, 120, of the meandering antenna 204, 205 represent the areas where the flip chip technology is applied to make an electrical connection respectively between the electrodes 126, 128 of sensor 100 and the ends 114, 120 of the antenna 204, 205.

The configuration depicted in FIGS. 1-4 thus generally describes a new concept of final packaging for wireless SAW quartz sensors. The concept can be used for chip packaging of any wireless sensor, wherein an antenna cannot be integrated on the chip itself. As an example, the embodiments described herein are intended to solve the problem of a robust technology for chip level packaging and antenna and impedance matching circuit fabrication on a flexible substrate needed by a wireless pressure sensor cured in, for example, rubber. An innovative solution for chip packaging specific to “cured in the rubber pressure sensor” with potential low cost is therefore described herein.

It will be appreciated that variations of the above-disclosed and other features and functions, or alternatives thereof, may be desirably combined into many other different systems or applications. Also that various presently unforeseen or unanticipated alternatives, modifications, variations or improvements therein may be subsequently made by those skilled in the art which are also intended to be encompassed by the following claims.

What is claimed is:

1. A sensor packaging system, comprising:
a plastic substrate configured to include a gap for receiving and maintaining an acoustic wave sensor; and
an antenna printed on said plastic substrate and connected electrically to said acoustic wave sensor for the transmission and receipt of data from and to said acoustic wave sensor.

2. The system of claim 1 wherein said antenna is flip chip surface mounted to said acoustic wave sensor.

3. The system of claim 1 wherein said acoustic wave sensor comprises a Surface Acoustic Wave (SAW) sensor chip comprising at least two quartz parts bonded to one another.

4. The system of claim 3 wherein said SAW sensor chip comprises a plurality of metal electrodes located on a same surface of a quartz substrate as said SAW sensor chip.

5. The system of claim 3 wherein an insulating polyimide selectively encapsulates at least one surface of said SAW sensor chip.

6. The system of claim 3 further comprising a sensing diaphragm maintained by said SAW sensor chip.

7. The system of claim 6 wherein said sensing diaphragm comprises a recessed area and wherein a gel that functions as a pressure transmitting element is located within said recessed area.

8. The system of claim 1 wherein said plastic substrate comprises a dielectric substrate.

9. The system of claim 8 wherein said dielectric substrate comprises a flexible substrate.

10. The system of claim 1 wherein said acoustic wave sensor comprises a quartz cover and wherein said gap formed in said plastic substrate accommodates said quartz cover.

11. The system of claim 1 wherein said antenna is printed directly on said plastic substrate by maskless ink-jet deposition.

12. The system of claim 1 wherein said acoustic wave sensor is mounted on said antenna with a plurality of bonding pads associated with said acoustic wave sensor positioned on a plurality of corresponding bonding pads associated with said antenna.

13. A sensor packaging system, comprising:
a dielectric substrate;
a wireless acoustic wave sensor comprising at least one quartz component; and
an antenna attached to said wireless acoustic wave sensor on said dielectric substrate utilizing ink-jet maskless printing, thereby providing a sensor for the wireless transmission and receipt of sensor data.

14. The system of claim 13 wherein said antenna printed on said dielectric substrate operates in a frequency range of approximately 100 KHz to 2.4 GHz.

15. The system of claim 13 wherein said dielectric substrate comprises a hole for maintaining said wireless acoustic wave sensor, wherein said hole is configured so that a cover associated with said wireless acoustic wave sensor can be accommodated therein for a decreased total thickness of said acoustic wave sensor.

16. The system of claim 13 further comprising a sensing diaphragm maintained by said wireless acoustic wave sensor, wherein said sensing diagram comprises a recessed area wherein a gel can be located that functions as a sensing element.

17. A sensor packaging method, comprising:
providing a dielectric substrate;
configuring a wireless acoustic wave sensor to comprise at least one quartz component, wherein said wireless acoustic wave sensor is connected to said dielectric substrate;
attaching an antenna to said wireless acoustic wave sensor on said dielectric substrate utilizing ink-jet maskless printing, thereby providing a sensor for the wireless transmission and receipt of sensor data.

18. The method of claim 17 further comprising:
configuring said dielectric substrate to include a hole for maintaining said wireless acoustic wave sensor; and
shaping said hole so that a cover associated with said wireless acoustic wave sensor can be accommodated therein for a decreased total thickness of said acoustic wave sensor.

19. The method of claim 18 further comprising:
providing a sensing diaphragm that is maintained by said wireless acoustic wave sensor; and
configuring said sensing diagram to include a recessed area; and
locating a gel with said recessed area, wherein said gel that functions as a sensing element.

20. The method of claim 18 further comprising:
providing said wireless acoustic wave sensor as a Surface Acoustic Wave (SAW) sensor chip;
configuring said SAW sensor chip to comprise a plurality of metal electrodes located on a same surface of a quartz substrate as said SAW sensor chip; and
providing an insulating polyimide that selectively encapsulates at least one surface of said SAW sensor chip.
